(19) United States
(12) Patent Application Publication
(10) Pub. No.: US 2018/0040798 A1
(43) Pub. Date: Feb. 8, 2018

(54) STRUCTURE OF THERMOELECTRIC MODULE AND FABRICATING METHOD THEREOF

(71) Applicant: Industrial Technology Research Institute, Hsinchu (TW)

(72) Inventors: Li-Ling Liao, Hsinchu City (TW); Ming-Ji Dai, Hsinchu City (TW); Chun-Kai Liu, Taipei City (TW); Cheng-Heng Kao, Taipei City (TW); Cheng-Chieh Li, Kaohsiung City (TW); Jeffrey Snyder, Pasadena, CA (US); Fivos Drymiotis, Seneca, SC (US)

(73) Assignee: Industrial Technology Research Institute, Hsinchu (TW)

(21) Appl. No.: 15/721,743

(22) Filed: Sep. 30, 2017

Related U.S. Application Data
(62) Division of application No. 14/562,784, filed on Dec. 8, 2014.

(51) Int. Cl. H01L 35/32; H01L 35/34

(52) U.S. Cl. CPC H01L 35/32; H01L 35/34

(57) ABSTRACT

A structure of a thermoelectric module including at least one substrate, a thermoelectric device and an insulation protection structure is provided. The thermoelectric device is disposed on the substrate. The insulation protection structure surrounds the thermoelectric device. The thermoelectric device includes at least three electrode plates, first type and second type thermoelectric materials and a diffusion barrier structure. First and second electrode plates among the three electrode plates are disposed on the substrate. The first type thermoelectric material is disposed on the first electrode plate. The second type thermoelectric material is disposed on the second electrode plate. A third electrode plate among the three electrode plates is disposed on the first type and second type thermoelectric materials. The diffusion barrier structure is disposed on two terminals of each of the first type and second type thermoelectric materials. A fabrication method of the foregoing thermoelectric module is also provided.

### CROSS-REFERENCE TO RELATED APPLICATION

This application is a divisional application of U.S. application Ser. No. 14/562,784, filed on Dec. 8, 2014, now pending. The entirety of the above-mentioned patent application is hereby incorporated by reference herein and made a part of this specification.

### TECHNICAL FIELD

The disclosure relates to a module structure and a fabrication method thereof, and more particularly, relates to a structure of a thermoelectric module and a fabrication method thereof.

### BACKGROUND

Application of thermoelectric modules in the field of waste heat recycling has become a hot trend. In response to an application temperature for waste heat, thermoelectric materials and thermoelectric modules at intermediate/high temperature have been gradually developed recently. However, an operating temperature of the thermoelectric material at intermediate temperature is in the range of 200 to 600° C., but melting points of Sn-rich solders used by the modules at low temperature are all below 232° C. When the application temperature is higher than 200° C., most of the solders melts and leads to issues such as structural collapse. To avoid aforementioned issue, the current thermoelectric module at intermediate temperature mainly adopts two fabrication methods, which are a diffusion bonding method and a brazing method. The diffusion bonding method is a method that directly performs a solid-solid bonding method for two solid state materials by applying pressure on and increasing an ambient temperature for the materials. As such, the purpose of bonding may be accomplished by an interdiffusion of atoms on a bonding interface. An ambient temperature for bonding is usually higher than one half the melting points of the two solid state materials in order to accelerate the interdiffusion of atoms. The purpose of applying pressure aims to eliminate voids formed by rough surfaces of two objects in contact with each other. The diffusion bonding method may cause serious problems in terms of oxidation. That is to say, a bonding quality may be affected if a stable oxide is formed on a surface of a bonding material at high temperature. For example, a figure of merit and a conversion efficiency of the thermoelectric module may be decreased by reduction of mechanical strength and increases in thermal resistance and electrical resistance. Further, a plastic deformation at the interface during the process of applying pressure may also lower functions of the materials.

Moreover, if the temperature is overly high when assembling the module, in addition to accelerated degradation of the thermoelectric material caused by the large number of interdiffusion of the atoms, a reliability issue induced by a coefficient of thermal expansion mismatch (CTE mismatch) may also arise. The thermoelectric module at low temperature often uses Ni as a diffusion barrier layer, which is capable of effectively blocking diffusions of Sn, Cu and Ag. However, Ni is prone to a diffusion reaction with Te in the thermoelectric material to thereby produce NiTe intermetallic compound. At the same time, Ni can easily be diffused into an N-type Bi2Te3 to affect a function of the thermoelectric material. Aforementioned two conditions both result in a performance degradation of the thermoelectric material. Furthermore, the related research indicates that if Ni is used as the diffusion barrier layer of a Pb0.5Sn0.5Te thermoelectric material at intermediate temperature, a complex intermetallic compound layer may be produced at an interface after assembling to cause significant increases in an interface resistance. Because such behavior reduces the effective figure of merit of the module, it is imperative to develop a more appropriate diffusion barrier layer as a replacement of Ni.

### SUMMARY

The disclosure is directed to a structure of a thermoelectric module and a fabrication method thereof, which are capable of providing a high temperature protection and a diffusion barrier function.

A structure of a thermoelectric module of the disclosure includes at least one substrate, a thermoelectric device, at least three electrode plates and an insulation protection structure. The thermoelectric device is disposed on the at least one substrate. The insulation protection structure is disposed surrounding the thermoelectric device. The thermoelectric device includes the at least three electrode plates, a first type thermoelectric material, a second type thermoelectric material and a diffusion barrier structure. A first electrode plate and a second electrode plate among the at least three electrode plates are disposed on the at least one substrate to serve as one terminal of the thermoelectric device. The first type thermoelectric material is disposed on the first electrode plate. One terminal of the first type thermoelectric material is electrically connected to the first electrode plate. The second type thermoelectric material is disposed on the second electrode plate. One terminal of the second type thermoelectric material is electrically connected to the second electrode plate. A third electrode plate among the at least three electrode plates is disposed on the first type thermoelectric material and the second type thermoelectric material to serve as another terminal of the thermoelectric device. The third electrode plate is electrically connected to another terminal of the first type thermoelectric material and another terminal of the second type thermoelectric material. The diffusion barrier structure is disposed on two terminals of each of the first type thermoelectric material and the second type thermoelectric material.

A fabricating method of thermoelectric module of the disclosure includes the following steps. A diffusion barrier structure is formed on two terminals of each of a first type thermoelectric material and a second type thermoelectric material. A first electrode plate and a second electrode plate among at least three electrode plates are disposed on at least one substrate to serve as one terminal of a thermoelectric device. The first type thermoelectric material and the second type thermoelectric material each having the two terminals including the diffusion barrier structure are disposed on the first electrode plate and the second electrode plate among the at least three electrode plates respectively. A third electrode plate among the at least three electrode plates is disposed on the first type thermoelectric material and the second type thermoelectric material each having the two terminals including the diffusion barrier structure to serve as another terminal of the thermoelectric device, so as to form the thermoelectric device. An insulation protection structure is formed surrounding the thermoelectric device, so as to form the thermoelectric module. One terminal of the first type thermoelectric material is electrically connected to the first electrode plate. One terminal of the second type thermoelectric material is electrically connected to the second electrode plate. The third electrode plate is electrically connected to another terminal of the first type thermoelectric material and another terminal of the second type thermoelectric material.

Based on the above, the thermoelectric module of the disclosure includes the insulation protection structure, which is capable of preventing the material of each of the devices and the layer structures from oxidation and degradation. The thermoelectric module of the disclosure includes the diffusion barrier structure in form of single layer or multi-layer, which is capable of providing functions of cushioning stress and solving the issue of the CTE mismatch.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a schematic diagram of a structure of thermoelectric module according to an exemplary embodiment of the disclosure.

FIG. 2 illustrates a fabrication method of thermoelectric bulk material according to an exemplary embodiment of the disclosure.

FIG. 3 illustrates a top view and a side view of a model of the insulation protection structure of FIG. 2.

FIG. 4 illustrates a fabrication method of thermoelectric module according to an exemplary embodiment of the disclosure.

FIG. 5 illustrates a schematic diagram of a structure of thermoelectric module according to an exemplary embodiment of the disclosure.

FIG. 6 illustrates a fabrication method of thermoelectric module according to an exemplary embodiment of the disclosure.

FIG. 7 illustrates a schematic diagram of a structure of thermoelectric module according to an exemplary embodiment of the disclosure.

FIG. 8 illustrates a schematic diagram of a structure of thermoelectric module according to an exemplary embodiment of the disclosure.

FIG. 9 illustrates a fabrication method of thermoelectric module according to an exemplary embodiment of the disclosure.

FIG. 10 illustrates a schematic diagram of a structure of thermoelectric module according to an exemplary embodiment of the disclosure.

FIG. 11 illustrates a schematic diagram of a structure of thermoelectric module according to an exemplary embodiment of the disclosure.

FIG. 12 illustrates a schematic diagram of a structure of thermoelectric module according to an exemplary embodiment of the disclosure.

FIG. 13 illustrates a fabrication method of thermoelectric module according to an exemplary embodiment of the disclosure.

FIG. 14 illustrates a schematic diagram of a structure of thermoelectric module according to an exemplary embodiment of the disclosure.

FIG. 15 illustrates a schematic diagram of a structure of a thermoelectric leg according to an exemplary embodiment of the disclosure.

FIG. 16 illustrates a schematic diagram of a structure of a thermoelectric leg according to an exemplary embodiment of the disclosure.

FIG. 17 illustrates a schematic diagram of a structure of a thermoelectric leg and a bonding structure according to an exemplary embodiment of the disclosure.

FIG. 18 illustrates a schematic diagram of a structure of a thermoelectric leg and a bonding structure according to an exemplary embodiment of the disclosure.

FIG. 19 illustrates a thermoelectric property diagram of a layer structure Ag/PbTe/Ag according to an exemplary embodiment of the disclosure.

### DETAILED DESCRIPTION OF DISCLOSED EMBODIMENTS

In general, as the application temperature of the current thermoelectric module continues to increase, spontaneous volatilization and precipitation may occur on a thermoelectric material due to such a high temperature load. In related parts, a periphery of the thermoelectric module is usually coated with only one sealing ring layer to ensure for a steady temperature inside the module, but such temperature may often be overly-high to cause a material oxidation or an air-blast in action. Moreover, in a thermoelectric module applied at intermediate/high temperature, a diffusion barrier layer is unable to suppress a diffusion reaction between the thermoelectric module and a material of a bonding structure under the high temperature load. The diffusion reaction between the materials of the structures can easily lead to production of intermetallic compounds, voids and fractures.

The disclosure proposes to utilize an insulation plastic material with high temperature resistance to directly cover a periphery of a thermoelectric bulk material as an insulation protection structure, so as to prevent the thermoelectric device from oxidation, material volatilization and precipitation caused by the high temperature. In the disclosure, manners for coating the insulation protection structure on the thermoelectric device may be divided into least two types. For example, one of the types is, for example, coating on thermoelectric legs, and the insulation protection structure in such manner directly covers a surface excluding two terminals of each of the thermoelectric devices served as the thermoelectric legs in a tightly-bonded fashion. That is to say, the insulation protection structure substantially covers a periphery of the thermoelectric device in this example. Another one of the types is, for example, complete coating on module gap, and the insulation protection structure in this manner substantially completely fills up a gap formed by a substrate, an electrode plate and a thermoelectric material. That is to say, the insulation protection structure substantially completely fills up a gap inside the module completely in this example. In addition, the insulation protection structure of the disclosure may also be a barrier structure disposed on the substrate. Such barrier structure surrounds all of the thermoelectric devices inside the thermoelectric module, and forms an enclosed space in a vacuum state together with upper and lower substrates or the electrode plates. On the other hand, when the thermoelectric materials are prepared as a bulk material during a hot pressing process, the disclosure combines use of the insulation protection structure with high temperature resistance to fabricate the thermoelectric material and a diffusion barrier structure together in batch, so as to reduce processes and time required for fabricating the thermoelectric module.

In addition, the disclosure provides a material with high melting point, such as a glass, an enamel lacquer and a ceramic, to serve as the insulation protection structure of the thermoelectric module at intermediate/high temperature, which is capable of preventing material properties from being affected by oxidation and volatilization occurred on the thermoelectric material under intermediate/high temperature load. Furthermore, the thermoelectric devices may be modulized to rapidly hot press the diffusion barrier structure and the thermoelectric materials to from thermoelectric legs in array, so as to significantly reduce a time required for fabricating the materials. The thermoelectric module of the disclosure also adopts use of a proper metal material to serve as the diffusion barrier structure of the thermoelectric module in order to suppress influences caused by interdiffusion of a metal material or a contact alloy of the bonding structure to the material of the thermoelectric material, and prevent production of the voids and the fractures to avoid an affect on a component reliability. Exemplary embodiments are provided below to describe the disclosure, but the disclosure is not limited to the provided exemplary embodiments, and the provided exemplary embodiments can be suitably combined.

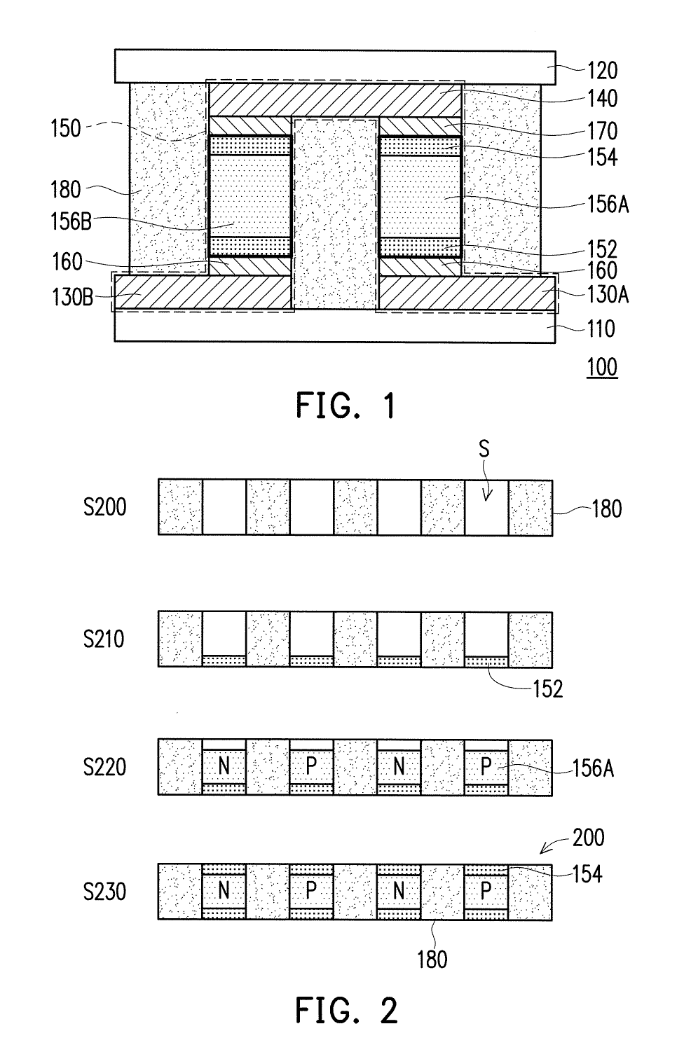

FIG. 1 illustrates a schematic diagram of a structure of a thermoelectric module according to an exemplary embodiment of the disclosure. Referring to FIG. 1, a thermoelectric module 100 of the present exemplary embodiment includes a first substrate 110, a second substrate 120 and at least one thermoelectric device 150. The thermoelectric device 150 includes a first electrode plate 130A, a second electrode plate 130B and a third electrode plate 140. The first substrate 110, the thermoelectric device 150 and the second substrate 120 form a stack structure. The first electrode plate 130A and the second electrode plate 130B are disposed on the first substrate 110 to serve as one terminal of the thermoelectric device 150. The third electrode plate 140 is disposed on a first type thermoelectric material 156A and a second type thermoelectric material 156B to serve as another terminal of the thermoelectric device 150. In the present exemplary embodiment, an assembling method of the thermoelectric module 100 includes, for example, bonding each of devices and layer structures to from the stack structure by a brazing method or a solid-liquid state interdiffusion bonding method or by utilizing a nano-silver material, but the disclosure is not limited thereto. In an exemplary embodiment, the assembling method of the thermoelectric module 100 may also achieve an electrical connection by a directly bonding method.

In the present exemplary embodiment, an insulation protection structure 180 is included at the periphery of the thermoelectric device 150 to at least prevent an output performance of the thermoelectric module 100 from being affected by oxidation, material volatilization, precipitation or degradation occurred on the first type thermoelectric material 156A and the second type thermoelectric material 156B under the high temperature load. In the present exemplary embodiment, a material of the insulation protection structure 180 is one selected from a glass, an enamel lacquer and a ceramic, but the disclosure is not limited thereto. In the present exemplary embodiment, the insulation protection structure 180 is completely coated on a gap inside the thermoelectric module 100. In other words, the insulation protection structure 180 substantially completely fills up the gap inside the thermoelectric module 100, and the gap is formed by the first substrate 110, the first electrode plate 130A, the second electrode plate 130B, the first type thermoelectric material 156A, the second type thermoelectric material 156B, the third electrode plate 140 and the second substrate 120. In an exemplary embodiment, it is also possible that the insulation protection structure 180 does not fill up a gap between the first type thermoelectric material 156A and the second type thermoelectric material 156B inside the thermoelectric module 100, such that a cavity state may be kept between the two.

In the present exemplary embodiment, the thermoelectric device 150 further includes the first type thermoelectric material 156A, the second type thermoelectric material 156B and a diffusion barrier structure. The diffusion barrier structure is disposed on two terminals of each of the first type thermoelectric material 156A and the second type thermoelectric material 156B. In the present exemplary embodiment, the two terminals of each of the first type thermoelectric material 156A and the second type thermoelectric material 156B include the diffusion barrier structure. That is, a first diffusion barrier layer 152 and a second diffusion barrier layer 154 are used to block interdiffusion of materials of first and second bonding structures 160 and 170 from the first type thermoelectric material 156A and the second type thermoelectric material 156B respectively. In the present exemplary embodiment, those located on the two terminals of each of the first type thermoelectric material 156A and the second type thermoelectric material 156B are the first and second diffusion barrier layers 152 and 154 in form of single layer, respectively, and a material thereof is, for example, one selected from Ag, Cu, Al and Ge. In another exemplary embodiment, the diffusion barrier structure may also include diffusion barrier layers in form of multi-layer structure, and a combination of materials thereof is, for example, one selected from Ag/Ge, Cu/Ge, Ag/C and Cu/C. As such, in addition to effectively blocking the interdiffusion of material components at the two sides and reducing stress, the issue of the coefficient of thermal expansion mismatch (CTE mismatch) may also be solved. It should be noted that, in the present exemplary embodiment, the amount and the selection of the materials of the diffusion barrier layers included in the diffusion barrier structure on the two terminals of each of the first type thermoelectric material 156A and the second type thermoelectric material 156B are merely examples, and the disclosure is not limited thereto. In an exemplary embodiment, the diffusion barrier layers in form of multi-layer structure may be integrated as one functional graded diffusion barrier layer composed of material layers with different components and concentrations. Likewise, the interdiffusion of material components at the two sides may be effectively blocked and stress may be reduced accordingly. In this example, the diffusion barrier layer may also be composed of a material with progressive components which is capable of cushioning stress and solving the issue of the CTE mismatch. In another exemplary embodiment, the diffusion barrier structure located on the two terminals of each of the first type thermoelectric material 156A and the second type thermoelectric material 156B may also be combined with the first and second bonding structures 160 and 170 respectively stacked thereon, so as to form a single layer structure.

In the present exemplary embodiment, the first type thermoelectric material 156A and the second type thermoelectric material 156B are electrically connected to each other by the first electrode plate 130A, the second electrode plate 130B and the third electrode plate 140. The first type thermoelectric material 156A and the second type thermoelectric material 156B may be connected in serial configuration or connected in parallel configuration, which are not particularly limited in the disclosure. In the present exemplary embodiment, the thermoelectric module 100 further includes the first bonding structure 160 and the second bonding structure 170. The first bonding structure 160 is disposed between the first type thermoelectric material 156A and the first electrode plate 130A, and disposed between the second type thermoelectric material 156B and the second electrode plate 130B. Accordingly, one terminal of the first type thermoelectric material 156A is electrically connected to the first electrode plate 130A, and one terminal of the second type thermoelectric material 156B is electrically connected to the second electrode plate 130B. The second bonding structure 170 is disposed between the first type thermoelectric material 156A and the third electrode plate 140, and disposed between the second type thermoelectric material 156B and the third electrode plate 140. Accordingly, another terminal of the first type thermoelectric material 156A and another terminal of the second type thermoelectric material 156B are electrically connected to the third electrode plate 140. The first bonding structure 160 is used as an assembly solder for bonding the first diffusion barrier layer 152 of the first type thermoelectric material 156A to the first electrode plate 130A and bonding the first diffusion barrier layer 152 of the second type thermoelectric material 156B to the second electrode plate 130B, and the second bonding structure 170 is used as an assembly solder for bonding the second diffusion barrier layer 154 of the first type thermoelectric material 156A and the second diffusion barrier layer 154 of the second type thermoelectric material 156B to the third electrode plate 140. In the present exemplary embodiment, the first bonding structure 160 and the second bonding structure 170 includes a metallic or non-metallic conductive material, which is not particularly limited in the disclosure. In the present exemplary embodiment, a forming method of the first bonding structure 160 and the second bonding structure 170 includes, but not limited to, an electroplating procedure, an electroless plating procedure, a sputtering deposition procedure or a chemical vapor deposition procedure. In an exemplary embodiment where the thermoelectric module 100 is assembled by a solid-liquid state interdiffusion bonding method, the first bonding structure 160 and the second bonding structure 170 may be a tin metallic film.

It should be noted that, although FIG. 1 only illustrates that the thermoelectric module 100 includes two thermoelectric modules (i.e., the first type thermoelectric material 156A and the second type thermoelectric material 156B) to serve as the thermoelectric legs of the thermoelectric device 150, but such amount is only an example and does not intend to limit the disclosure. From the top perspective, the first type thermoelectric material 156A and the second type thermoelectric material 156B may be disposed on the first substrate 110 in the form of an array, so as to form a plurality of the thermoelectric devices 150. In the present exemplary embodiment, the first type thermoelectric material 156A and the second type thermoelectric material 156B include a material capable of converting heat into electricity, such as a P-type thermoelectric material or an N-type thermoelectric material. For instance, each of thermoelectric materials 156 includes Bi2Te3, GeTe, PbTe, CoSb3 or Zn4Sb3-series alloy materials, but the disclosure is not limited thereto. In the present exemplary embodiment, the first type thermoelectric material 156A is, for example, the P-type thermoelectric material, and the second type thermoelectric material 156B is, for example, the N-type thermoelectric material. However, the disclosure is not limited thereto. In an exemplary embodiment, the first type thermoelectric material I 56A is, for example, the N-type thermoelectric material, and the second type thermoelectric material 156B is, for example, the P-type thermoelectric material.

In the present exemplary embodiment, the material of the diffusion barrier layer may form an intermetallic compound together with the first type thermoelectric material 156A and the second type thermoelectric material 156B in order to at least improve an operating performance of the thermoelectric device 150. In an exemplary embodiment where the material of the diffusion barrier layer is Ag and each of the thermoelectric materials is a PbTe alloy material, an Ag2Te intermetallic compound may be formed between the diffusion barrier layer and each of the thermoelectric materials to increase a figure of merit coefficient of the thermoelectric device.

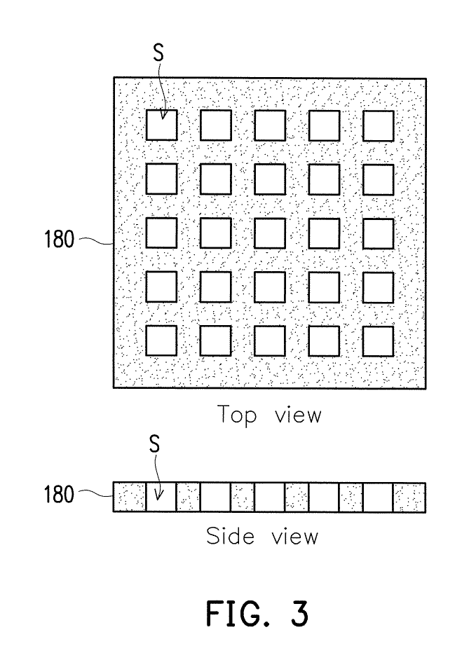

FIG. 2 illustrates a fabrication method of thermoelectric bulk material according to an exemplary embodiment of the disclosure. FIG. 3 illustrates a top view and a side view of a model of the insulation protection structure of FIG. 2. Referring to FIG. 1 to FIG. 3 and taking the thermoelectric module 100 of FIG. 1 as an example, before bonding the substrates 110 and 120, the first electrode plate 130A, the second electrode plate 130B and the third electrode plate 140 to the first type thermoelectric material 156A and the second type thermoelectric material 156B, the disclosure may pre-fabricate a thermoelectric bulk material 200 in batch, which includes the first type thermoelectric material 156A, the second type thermoelectric material 156B and the diffusion barrier structures 152 and 154. In the present exemplary embodiment, a model of the insulation protection structure 180 is made by forming a plurality of device installation spaces S arranged in an array on an insulation protection bulk material, as shown by step S200 of FIG. 2. Accordingly, FIG. 3 illustrates only the model of the insulation protection structure 180 in which the first type thermoelectric material 156A and the second type thermoelectric material 156B are not yet formed in the device installation spaces S. Next, in step S210, the first diffusion barrier layer 152 is formed in each of the device installation spaces S. Thereafter, in step S220, the first type thermoelectric material 156A and the second type thermoelectric material 156B are formed on the different first diffusion barrier layers 152. Then, in step S230, the second diffusion barrier layer 154 is formed on each of the first type thermoelectric material 156A and the second type thermoelectric material 156B. At this point, the thermoelectric bulk material 200 of the present exemplary embodiment is completed, and the first type thermoelectric material 156A and the second type thermoelectric material 156B are formed in each of the device installation spaces S to serve as the thermoelectric legs. That is to say, the thermoelectric legs of the stack structure are formed in the device installation spaces S by the first diffusion barrier layer 152, the first type thermoelectric material 156A, the second type diffusion barrier layer 156B and the second diffusion barrier layer 154. In the present exemplary embodiment, a forming method of the first diffusion barrier layer 152 and the second diffusion barrier layer 154 includes, but not limited to, an electroplating procedure, an electroless plating procedure, a sputtering deposition procedure or a chemical vapor deposition procedure. In the present exemplary embodiment, the fabrication method of the thermoelectric bulk material 200 includes, for example, performing a direct hot pressing by utilizing the model of insulation protection structure with high temperature resistance to form the array-type thermoelectric bulk material 200, in which each of the device installation spaces S contains the diffusion barrier layers and the thermoelectric material formed by hot pressing at the same time in order to reduce time for fabricating the thermoelectric material bulk and assembling the module.

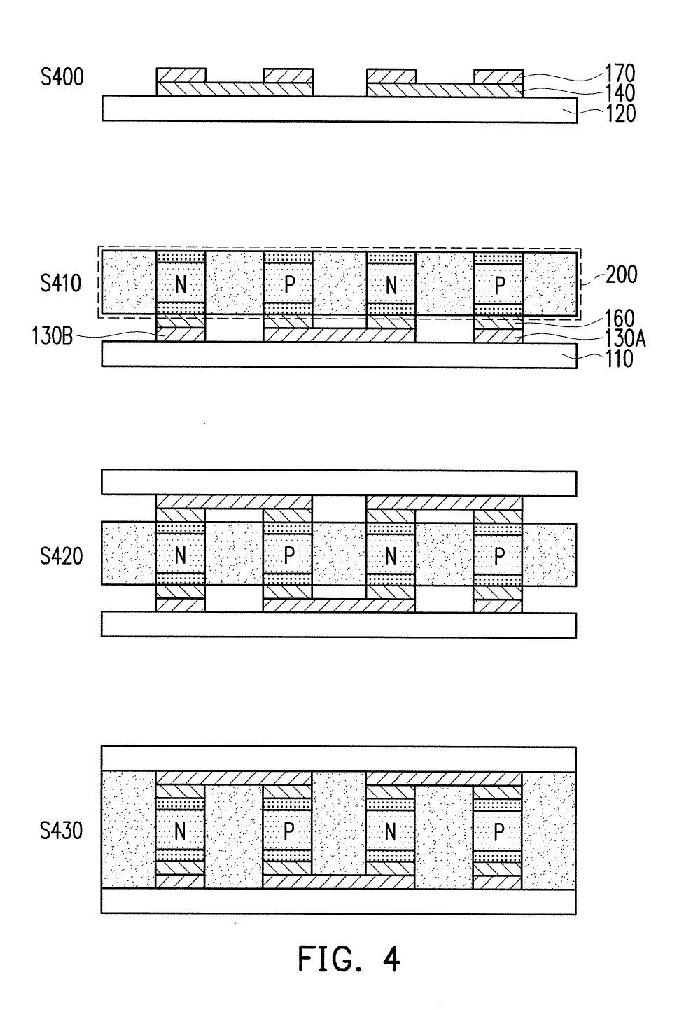

FIG. 4 illustrates a fabrication method of thermoelectric module according to an exemplary embodiment of the disclosure. Referring to FIG. 1 and FIG. 4 and taking the thermoelectric module 100 of FIG. 1 as an example, in the present exemplary embodiment, first of all, the second substrate 120 on which the third electrode plate 140 and the second bonding structure 170 are already formed in advance is provided in step S400. Next, in step S410, the thermoelectric bulk material 200 is disposed on the first substrate 110. In this step, the first electrode plate 130A, the second electrode plate 130B and the first bonding structure 160 are already formed in advance on the first substrate 110. In the present exemplary embodiment, the thermoelectric bulk material 200 is, for example, fabricated in batch by using the fabrication method depicted in FIG. 2, but the disclosure is not limited thereto. Thereafter, in step S420, the first substrate 110 and the second substrate 120 are assembled to form a stack structure including the first substrate 110, the first electrode plate 130A, the second electrode plate 130B, the first type thermoelectric material 156A, the second type thermoelectric material 156B, the third electrode plate 140 and the second substrate 120. In this step, an assembling method of the thermoelectric module 100 includes, for example, bonding each of the devices and the layer structures by a brazing method or a solid-liquid state interdiffusion bonding method or by utilizing a nano-silver material in order to from the stack structure. In an exemplary embodiment, the assembling method of the thermoelectric module 100 may also include bonding each of the devices and the layer structures by performing a hot pressing procedure or a direct bonding procedure, which are not particularly limited in the disclosure. Next, in step S430, the gap of the thermoelectric module 100 is filled up by the insulation protection structure 180 to fully protect each of the devices and the layer structures.

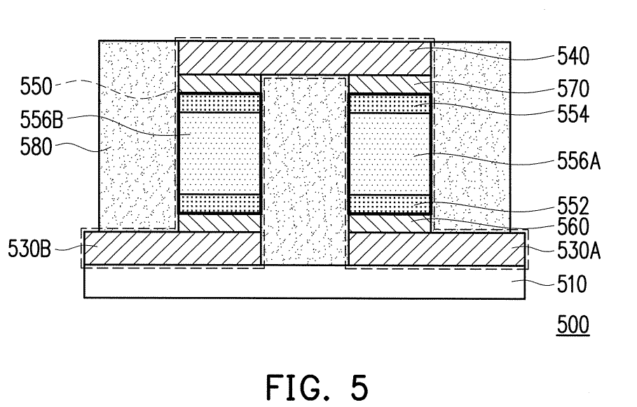

FIG. 5 illustrates a schematic diagram of a structure of a thermoelectric module according to another exemplary embodiment of the disclosure. Referring to FIG. 1 and FIG. 5, a thermoelectric module 500 of the present exemplary embodiment is similar to the thermoelectric module 100 of the exemplary embodiment in FIG. 1, and a difference between the two is that, for example, the thermoelectric module 500 of the present exemplary embodiment does not include the second substrate 120. In the present exemplary embodiment, when the thermoelectric module 500 not including the second substrate is applied in a thermoelectric conversion, a third electrode plate 540 thereof is, for example, directly attached to a hot source without going through the second substrate. This method may prevent a material degradation of the second substrate caused by the second substrate being attached on the hot source over a long period of time, or prevent a thermoelectric conversion efficiency and an output performance of the thermoelectric module 500 from being affected by physical or chemical changes generated between materials of the second substrate and the third substrate 540.

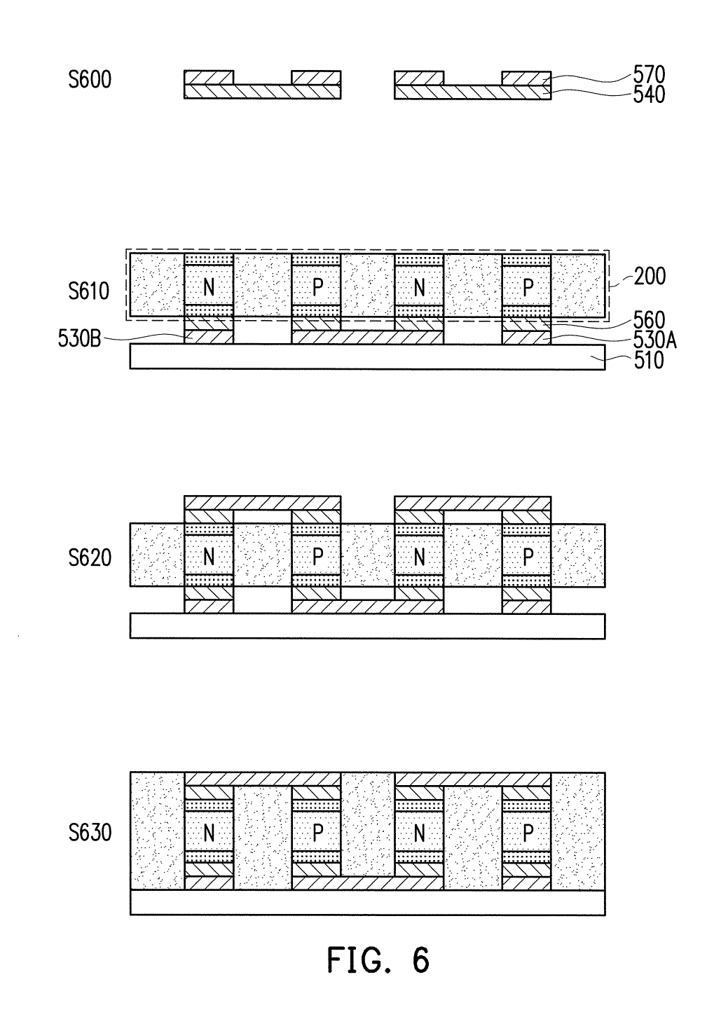

FIG. 6 illustrates a fabrication method of thermoelectric module according to another exemplary embodiment of the disclosure. Referring to FIG. 4 to FIG. 6, the fabrication method of thermoelectric module of the present exemplary embodiment is similar to the fabrication method of thermoelectric module of the exemplary embodiment in FIG. 4, and the major differences between the two are described as follows. Take the thermoelectric module 500 of FIG. 5 as an example, in the present exemplary embodiment, in step S600, the third electrode plate 540 on which a second bonding structure 570 is already formed in advance is provided. Further, a stack structure assembled in step S620 includes a first substrate 510, a first electrode plate 530A, a second electrode plate 530B, a first type thermoelectric material 556A, a second type thermoelectric material 556B and the third electrode plate 540, but does not include the second substrate.

In addition, enough teaching, suggestion, and implementation illustration for the thermoelectric module 500 and the fabrication method thereof according to the present exemplary embodiment of the disclosure may be obtained from the above exemplary embodiments depicted in FIG. 1 to FIG. 4, and thus related descriptions are not repeated hereinafter.

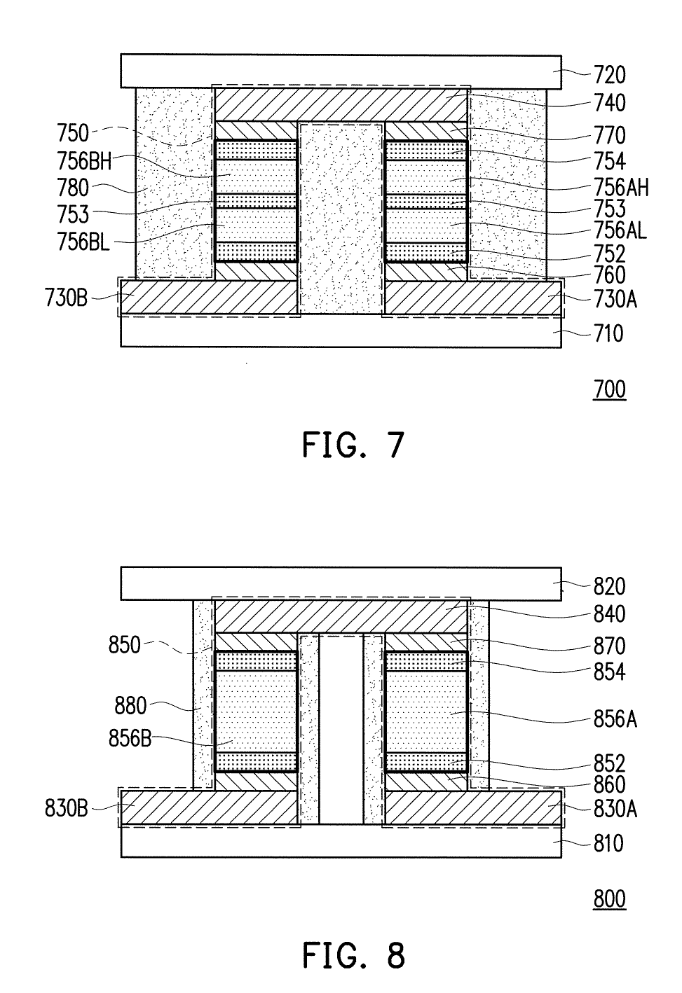

FIG. 7 illustrates a schematic diagram of a structure of a thermoelectric module according to another exemplary embodiment of the disclosure. Referring to FIG. 1 to FIG. 7, a thermoelectric module 700 of the present exemplary embodiment is similar to the thermoelectric module 100 of the exemplary embodiment in FIG. 1, and the major differences between the two are described as follows. In the thermoelectric module 700 of the present exemplary embodiment, a stack structure of first type thermoelectric materials 756AH and 756AL and a stack structure of second type thermoelectric materials 756BH and 756BL are used to serve as the thermoelectric legs, so as to improve an output performance of the thermoelectric module 700. The thermoelectric materials 756AH, 756AL, 756BH and 756BL may select a corresponding material system according to different temperature terminals. When being applied in a thermoelectric conversion, a first substrate 710 and a second substrate 720 are, for example, application terminals close to a cool source and a hot source respectively. Accordingly, each of the thermoelectric materials 756AH, 756AL, 756BH and 756BL may select a suitable material system to satisfy the actual application requirements. In the present exemplary embodiment, a third diffusion barrier layer 753 is further included between the first type thermoelectric materials 756AH and 756AL, and the third diffusion barrier layer 753 is also included between the second type thermoelectric materials 756BH and 756BL. The third diffusion barrier layer 753 is configured to block interdiffusion between material molecules of the thermoelectric materials 756AH, 756AL, 756BH and 756BL, so as to prevent a thermoelectric conversion efficiency and an output performance of the thermoelectric module 700 from being affected. In another exemplary embodiment, it is also possible that the thermoelectric module 700 does not include the second substrate 120.

In addition, enough teaching, suggestion, and implementation illustration for the thermoelectric module 700 and the fabrication method thereof according to the present exemplary embodiment of the disclosure may be obtained from the above exemplary embodiments depicted in FIG. 1 to FIG. 6, and thus related descriptions are not repeated hereinafter.

FIG. 8 illustrates a schematic diagram of a structure of a thermoelectric module according to another exemplary embodiment of the disclosure. Referring to FIG. 1 and FIG. 8, a thermoelectric module 800 of the present exemplary embodiment is similar to the thermoelectric module 100 of the exemplary embodiment in FIG. 1, and a difference between the two is that, for example, an insulation protection structure 880 of the present exemplary embodiment is in the manner of coating on thermoelectric legs. In the present exemplary embodiment, the insulation protection structure 880 directly covers a surface excluding two terminals of each of a first type thermoelectric material 856A and a second type thermoelectric material 856B served as the thermoelectric legs in a tightly-bonded fashion. That is, the insulation protection structure 880 substantially covers a periphery of a thermoelectric device 850 in this example.

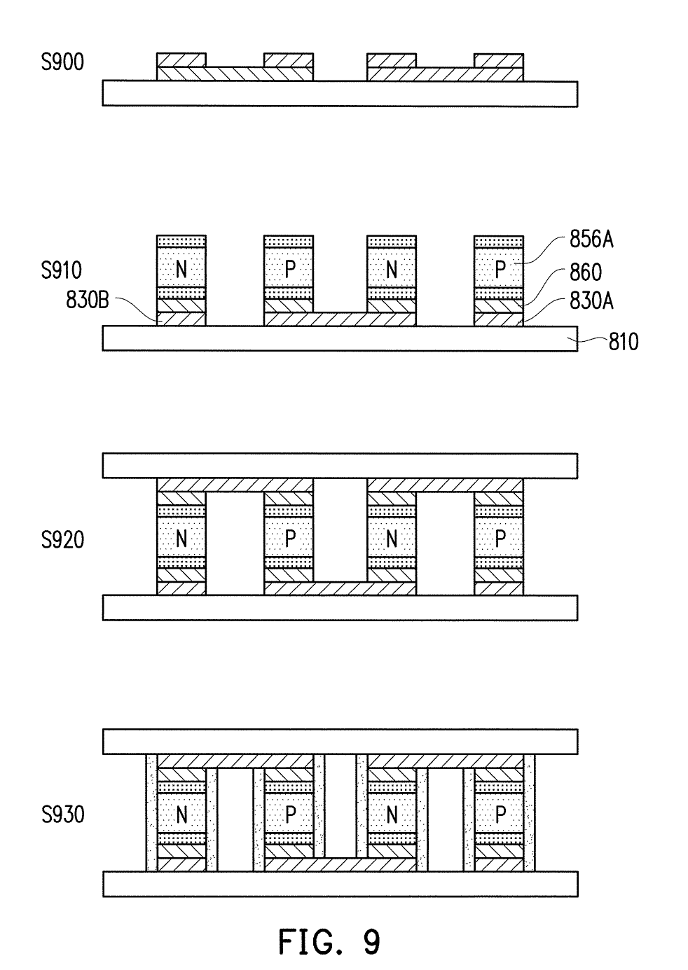

FIG. 9 illustrates a fabrication method of thermoelectric module according to another exemplary embodiment of the disclosure. Referring to FIG. 8 and FIG. 9, a fabrication method of thermoelectric module of the present exemplary embodiment is similar to the fabrication method of thermoelectric module of the exemplary embodiment in FIG. 4, and the major differences between the two are described as follows. Take the thermoelectric module 800 of FIG. 8 as an example, in the present exemplary embodiment, in step S910, a first substrate 810 is provided, on which a first electrode plate 830A, a second electrode plate 830B and a first bonding structure 860 are already formed in advance, and a plurality of the thermoelectric devices 850 arranged in an array are already fabricated in batch. In this step, peripheries of the first type thermoelectric material 856A and the second type thermoelectric material 856B are not yet covered by the insulation protection structure 880. Further, in step S930, the assembled and bonded thermoelectric module 800 is soaked into an insulation material with heat resistance in liquid state or in molten state and then pulled out for curing, or the insulation material with heat resistance are sprayed at the peripheries of the first type thermoelectric material 856A and the second type thermoelectric material 856B (i.e., forming the insulation material with heat resistance surrounding the first type thermoelectric material 856A and the second type thermoelectric material 856B by ways of spraying or soaking), so as to from the insulation protection structure 880 for protecting each of the devices and the layer structures. Therefore, in the exemplary embodiments of the disclosure, the insulation protection structure does not necessarily need to be extended to peripheries of the substrates.

In addition, enough teaching, suggestion, and implementation illustration for the thermoelectric module 800 and the fabrication method thereof according to the present exemplary embodiment of the disclosure may be obtained from the above exemplary embodiments depicted in FIG. 1 to FIG. 4, and thus related descriptions are not repeated hereinafter.

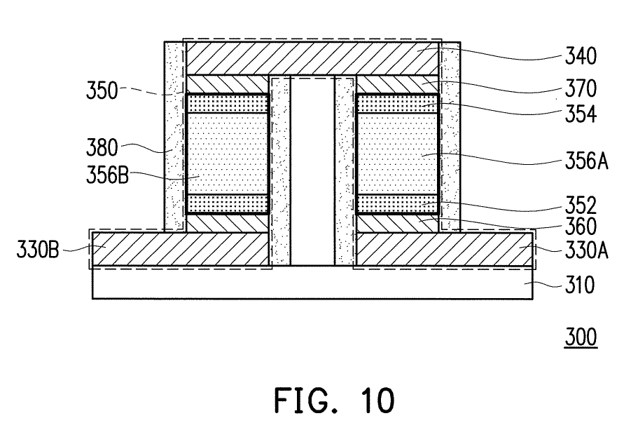

FIG. 10 illustrates a schematic diagram of a structure of a thermoelectric module according to another exemplary embodiment of the disclosure. Referring to FIG. 8 and FIG. 10, a thermoelectric module 300 of the present exemplary embodiment is similar to the thermoelectric module 800 of the exemplary embodiment in FIG. 8, and a difference between the two is that, for example, the thermoelectric module 300 of the present exemplary embodiment does not include the second substrate 820. In the present exemplary embodiment, when the thermoelectric module 300 not including the second substrate is applied in a thermoelectric conversion, a third electrode plate 340 thereof is, for example, directly attached to a hot source without going through the second substrate. This method may prevent a material degradation of the second substrate caused by the second substrate being attached on the hot source over a long period of time, or prevent a thermoelectric conversion efficiency and an output performance of the thermoelectric module 300 from being affected by physical or chemical changes generated between materials of the second substrate and the third substrate.

In addition, enough teaching, suggestion, and implementation illustration for the thermoelectric module 300 and the fabrication method thereof according to the present exemplary embodiment of the disclosure may be obtained from the above exemplary embodiments depicted in FIG. 6, FIG. 8 and FIG. 9, and thus related descriptions are not repeated hereinafter.

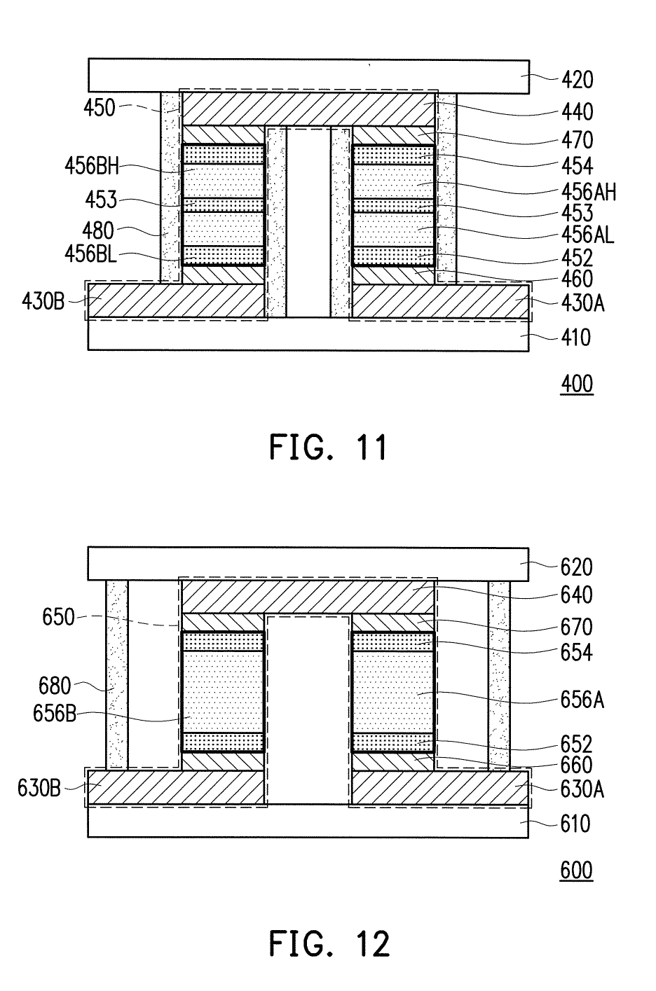

FIG. 11 illustrates a schematic diagram of a structure of a thermoelectric module according to another exemplary embodiment of the disclosure. Referring to FIG. 8 to FIG. 11, a thermoelectric module 400 of the present exemplary embodiment is similar to the thermoelectric module 800 of the exemplary embodiment in FIG. 8, and the major differences between the two are described as follows. In the thermoelectric module 400 of the present exemplary embodiment, a stack structure of first type thermoelectric materials 456AH and 456AL and a stack structure of second type thermoelectric materials 456BH and 456BL are used to serve as the thermoelectric legs, so as to improve an output performance of the thermoelectric module 400. The thermoelectric materials 456AH, 456AL, 456BH and 456BL may select a corresponding material system according to different temperature terminals. When being applied in a thermoelectric conversion, a first substrate 410 and a second substrate 420 are, for example, application terminals close to a cool source and a hot source respectively. Accordingly, each of the thermoelectric materials 456AH, 456AL, 456BH and 456BL may select a suitable material system to satisfy the actual application requirements. In the present exemplary embodiment, a third diffusion barrier layer 453 is further included between the thermoelectric materials 456AH and 456AL, and the third diffusion barrier layer 453 is also included between the thermoelectric materials 456BH and 456BL. The third diffusion barrier layer 453 is configured to block interdiffusion between material molecules of the thermoelectric materials 456AH, 456AL, 456BH and 456BL, so as to prevent a thermoelectric conversion efficiency and an output performance of the thermoelectric module 400 from being affected. In another exemplary embodiment, it is also possible that the thermoelectric module 400 does not include the second substrate 870.

In addition, enough teaching, suggestion, and implementation illustration for the thermoelectric module 400 and the fabrication method thereof according to the present exemplary embodiment of the disclosure may be obtained from the above exemplary embodiments depicted in FIG. 8 to FIG. 10, and thus related descriptions are not repeated hereinafter.

FIG. 12 illustrates a schematic diagram of a structure of a thermoelectric module according to another exemplary embodiment of the disclosure. Referring to FIG. 1 and FIG. 12, a thermoelectric module 600 of the present exemplary embodiment is similar to the thermoelectric module 100 of the exemplary embodiment in FIG. 1, and a difference between the two is that, for example, an insulation protection structure 680 of the present exemplary embodiment is a barrier structure disposed on the substrate. Such barrier structure 680 surrounds all of the thermoelectric devices inside the thermoelectric module 650, and forms an enclosed space in a vacuum state together with upper and lower substrates or the electrode plates, so as to protect each of the devices and the layer structures inside the thermoelectric module 600. In other words, in view of the schematic diagram illustrated in FIG. 12, a dam bar is placed surrounding the thermoelectric module 600 to serve as the barrier structure 680 such that the thermoelectric module 600 is formed as a sealed structure. An inner section the thermoelectric module 600 is in a vacuum state, and the dam bar is identical to the insulation material and capable of preventing the materials of each of the devices and the layer structures from oxidation and degradation.

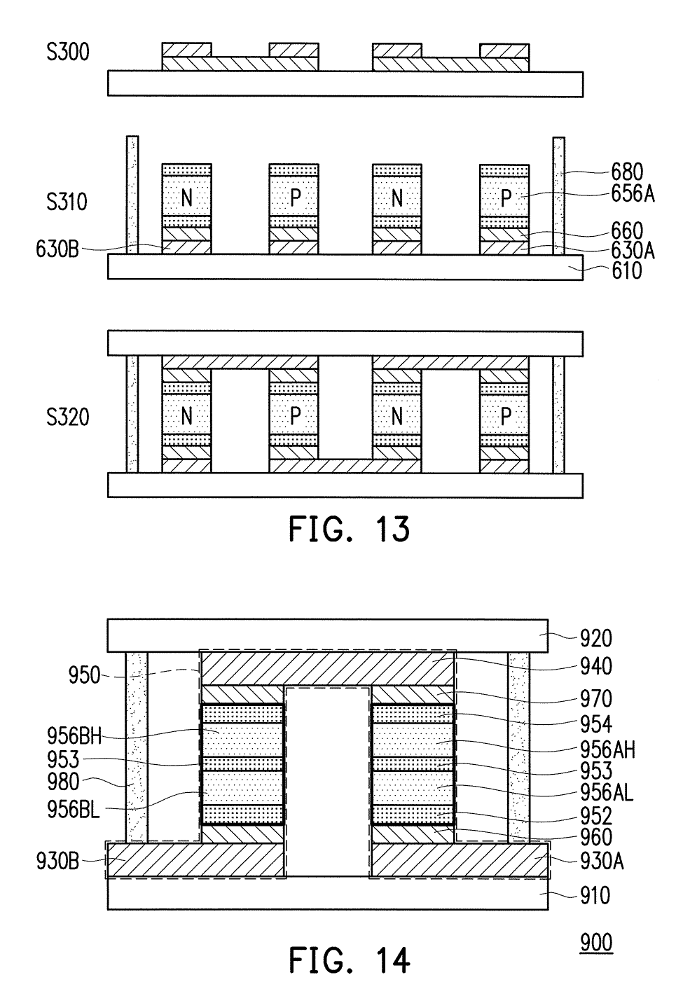

FIG. 13 illustrates a fabrication method of thermoelectric module according to another exemplary embodiment of the disclosure. Referring to FIG. 12 and FIG. 13, a fabrication method of thermoelectric module of the present exemplary embodiment is similar to the fabrication method of thermoelectric module of the exemplary embodiment in FIG. 8, and the major differences between the two are described as follows. Take the thermoelectric module 600 of FIG. 12 as an example, in the present exemplary embodiment, in step S310, a first substrate 610 is provided, on which the insulation protection structure 680, a first electrode plate 630A, a second electrode plate 630B and a first bonding structure 660 are formed in advance, and a plurality of first type thermoelectric materials 656A and a plurality of second type thermoelectric materials 656B arranged in an array are already fabricated in batch. In this step, a forming method of the insulation protection structure 680 may also include additionally disposing the barrier structure on the substrate. Alternatively, as similar to step S200 in FIG. 2, device installation spaces are formed on an insulation protection bulk material, and the device installation spaces are large enough to accommodate the first type thermoelectric materials 656A and the second type thermoelectric materials 656B arranged in the array. Thereafter, the first type thermoelectric materials 656A and the second type thermoelectric materials 656B are disposed into said device installation spaces. Moreover, in the present exemplary embodiment, steps S300 to S320 are performed, for example, in a vacuum environment, so as to ensure that the inner section of the thermoelectric module 600 is in a vacuum state. In an exemplary embodiment, if the inner section of the thermoelectric module 600 is not in the vacuum state, the inner section of the thermoelectric module 600 may also be filled up with nitrogen, so as to prevent the materials of each of the devices and the layer structures from oxidation and degradation.

In addition, enough teaching, suggestion, and implementation illustration for the thermoelectric module 600 and the fabrication method thereof according to the present exemplary embodiment of the disclosure may be obtained from the above exemplary embodiments depicted in FIG. 1 to FIG. 4, and thus related descriptions are not repeated hereinafter.

FIG. 14 illustrates a schematic diagram of a structure of a thermoelectric module according to another exemplary embodiment of the disclosure. Referring to FIG. 12 to FIG. 14, a thermoelectric module 900 of the present exemplary embodiment is similar to the thermoelectric module 600 of the exemplary embodiment in FIG. 12, and the major differences between the two are described as follows. In the thermoelectric module 900 of the present exemplary embodiment, a stack structure of first type thermoelectric materials 956AH and 956AL and a stack structure of second type thermoelectric materials 956BH and 956BL are used to serve as the thermoelectric legs, so as to improve an output performance of the thermoelectric module 900. The thermoelectric materials 956AH, 956AL, 956BH and 956BL may select a corresponding material system according to different temperature terminals. When being applied in a thermoelectric conversion, a first substrate 910 and a second substrate 920 are, for example, application terminals close to a cool source and a hot source respectively. Accordingly, each of the thermoelectric materials 956AH, 956AL, 956BH and 956BL may select a suitable material system to satisfy the actual application requirements. In the present exemplary embodiment, a third diffusion barrier layer 953 is further included between the thermoelectric materials 956AH and 956AL, and the third diffusion barrier layer 953 is also included between the thermoelectric materials 956BH and 956BL. The third diffusion barrier layer 953 is configured to block interdiffusion between material molecules of the thermoelectric materials 956AH, 956AL, 956BH and 956BL, so as to prevent a thermoelectric conversion efficiency and an output performance of the thermoelectric module 900 from being affected.

In addition, enough teaching, suggestion, and implementation illustration for the thermoelectric module 900 and the fabrication method thereof according to the present exemplary embodiment of the disclosure may be obtained from the above exemplary embodiments depicted in FIG. 12 to FIG. 13, and thus related descriptions are not repeated hereinafter.

In the disclosure, the diffusion barrier structure located on the two terminals may include one or more diffusion barrier layers. Exemplary embodiments are provided below to describe the diffusion barrier structure, but the disclosure is not limited to the provided exemplary embodiments, and the provided exemplary embodiments can be suitably combined.

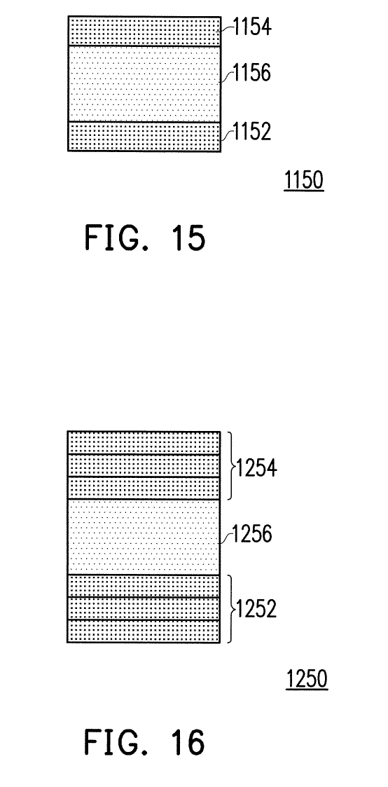

FIG. 15 illustrates a schematic diagram of a structure of a thermoelectric leg according to an exemplary embodiment of the disclosure. Referring to FIG. 15, a thermoelectric leg 1150 of the present exemplary embodiment includes a thermoelectric material 1156 and diffusion barrier structures 1152 and 1154. The diffusion barrier structures 1152 and 1154 are located at two terminals of the thermoelectric material 1156, and three of them font a stack structure. In the present exemplary embodiment, each of the diffusion barrier structures 1152 and 1154 is a layer structure in form of single layer, and a material thereof is, for example, one selected from Ag, Cu, Al and Ge. Selections on the materials for the first and second diffusion barrier layers 1152 and 1154 may be identical or different, which are not limited in the disclosure. A method of forming the diffusion barrier structures 1152 and 1154 on the two terminals of the thermoelectric material 1156 includes, but not limited to, an electroplating procedure, an electroless plating procedure, a sputtering deposition procedure or a chemical vapor deposition procedure. In the present exemplary embodiment, the thermoelectric material 1156 is, for example, the P-type thermoelectric material or the N-type thermoelectric material.

FIG. 16 illustrates a schematic diagram of a structure of a thermoelectric leg according to another exemplary embodiment of the disclosure. Referring to FIG. 16, a thermoelectric leg 1250 of the present exemplary embodiment includes a thermoelectric material 1256 and diffusion barrier structures 1252 and 1254. The diffusion barrier structures 1252 and 1254 are located at two terminals of the thermoelectric material 1256, and three of them form a stack structure. In the example of the present exemplary embodiment where the layer structure is of three layers, a combination of materials of the layer structures includes, for example, Ag, Ni and Cu. In an example where the layer structure is of double layers, a combination of materials is one selected from Ag/Ge, Cu/Ge, Ag/C and Cu/C. Take the layer structure in double layer as an example, a combination of materials is one selected from Ag/Ge, Cu/Ge, Ag/C and Cu/C. Selections on the materials for the diffusion barrier structures 1252 and 1254 may be identical or different, which are not limited in the disclosure. In the present exemplary embodiment, the thermoelectric material 1256 is, for example, the P-type thermoelectric material or the N-type thermoelectric material.

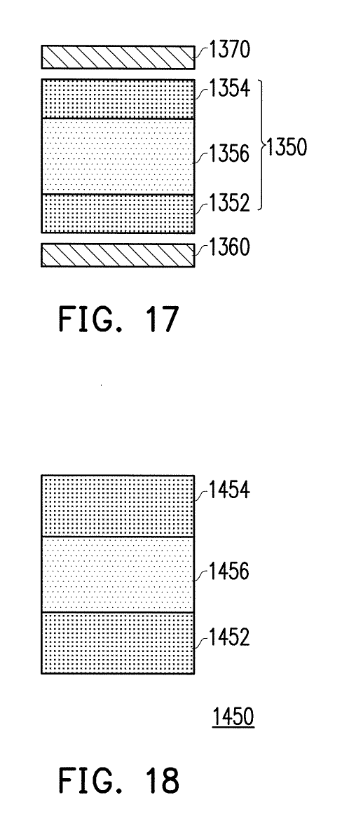

FIG. 17 illustrates a schematic diagram of a structure of thermoelectric leg and a bonding structure according to another exemplary embodiment of the disclosure. Referring to FIG. 17, a thermoelectric leg 1350 of the present exemplary embodiment includes a thermoelectric material 1356 and diffusion barrier structures 1352 and 1354. The diffusion barrier structures 1352 and 1354 are located at two terminals of the thermoelectric material 1356, and three of them form a stack structure. FIG. 17 further illustrates two bonding structures (first and second bonding structures 1360 and 1370) which are disposed respectively on the top and the bottom of the thermoelectric leg 1350. In the present exemplary embodiment, the diffusion barrier structures 1352 and 1354 are composed of material layers with different components and concentrations to separately form a functional graded diffusion barrier layer, which is also capable of effectively blocking the interdiffusion of material components at the two sides and reducing stress. In this example, the diffusion barrier layer is, for example, composed of a material with progressive components capable of cushioning stress and solving the issue of the CTE mismatch. In the present exemplary embodiment, the thermoelectric material 1356 is, for example, the P-type thermoelectric material or the N-type thermoelectric material.

FIG. 18 illustrates a schematic diagram of a structure of thermoelectric leg and a bonding structure according to another exemplary embodiment of the disclosure. Referring to FIG. 18, a thermoelectric leg 1450 of the present exemplary embodiment includes a thermoelectric material 1456 and diffusion barrier structures 1452 and 1454 combined with a bonding structure. The diffusion barrier structures 1452 and 1454 are located at two terminals of the thermoelectric material 1456, and three of them form a stack structure. In the present exemplary embodiment, the bonding structure reacts with the diffusion barrier structures 1452 and 1454 respectively to from a layer structure of an intermetallic compound, and this layer structure is a solderable functional gradient diffusion barrier layer. For instance, the bonding structure is, for example, a tin metallic film, and the diffusion barrier structures 1452 and 1454 include, for example, Ag, Ni or a Cu metallic films. After a pressing and heating treatment procedure is performed, the bonding structure reacts with the diffusion barrier structures 1452 and 1454 to form AgSn, NiSn or CuSn alloy intermetallic compound. In an exemplary embodiment, the tin metallic film completely reacts to form the AgSn, NiSn or CuSn alloy intermetallic compound while the Ag, Ni or Cu metallic films are partially remained. In the present exemplary embodiment, the thermoelectric material 1456 is, for example, the P-type thermoelectric material or the N-type thermoelectric material.

In the present exemplary embodiment, the material of the diffusion barrier layer may form the intermetallic compound together with each of the thermoelectric materials in order to at least improve an operating performance of the thermoelectric device. In an exemplary embodiment where the material of the diffusion barrier layer is Ag and each of the thermoelectric materials is a PbTe alloy material, an Ag2Te intermetallic compound may be formed between the diffusion barrier layer and each of the thermoelectric materials.

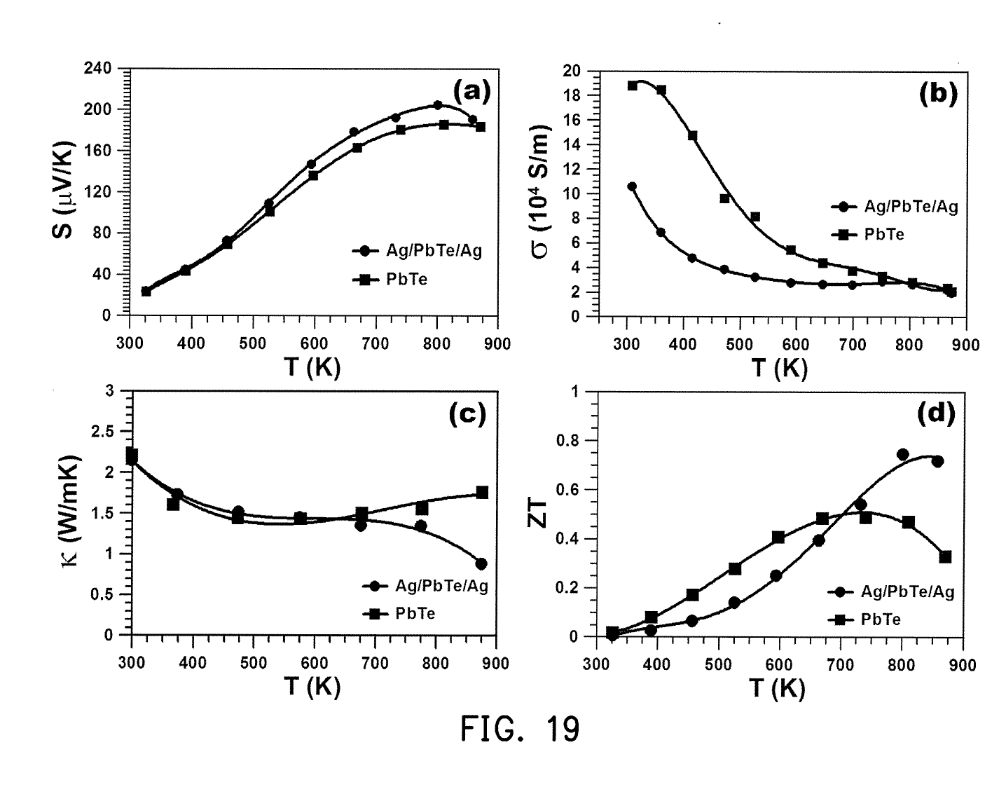

FIG. 19 illustrates a thermoelectric property diagram of a layer structure Ag/PbTe/Ag according to an exemplary embodiment of the disclosure. In the present exemplary embodiment, a diffusion barrier layer Ag of the layer Ag/PbTe/Ag layer structure forms an Ag2Te intermetallic compound together with each of the thermoelectric materials PbTe. Referring to FIG. 19, FIG. 19(a) shows that within a measurement range, a Seebeck coefficient S of the layer structure Ag/PbTe/Ag is greater than a Seebeck coefficients S of a single layer structure PbTe. FIG. 19(b) shows an electrical conductance σ of the two being decreased with increases of temperature. FIG. 19(c) shows that within an absolute temperature range of 300K to 630K, a thermal conductivity κ of the entire single layer structure PbTe is less than a thermal conductivity κ of the layer structure Ag/PbTe/Ag. Further, when the absolute temperature is higher than 630K, thermal conductivity κ of the layer structure Ag/PbTe/Ag gradually increases. FIG. 19(d) shows that, when Ag is used as the diffusion barrier layer for the PbTe thermoelectric material, an Ag-doping effect may be provided to increase a figure of merit coefficient ZT of the thermoelectric device. An efficiency of the thermoelectric material may be defined by ZT=S2σT/(κe+κL), wherein S is a thermo-electromotive force or the Seebeck coefficient, σ is the electrical conductance, T is the temperature, and κe and κL are thermal conductivities of electron and phonon respectively.

In summary, the thermoelectric module of the disclosure includes the insulation protection structure, which is capable of preventing the materials of each of the devices and the layer structures from oxidation and degradation. The fabrication method of thermoelectric module of the disclosure may be used to fabricate the thermoelectric materials and the diffusion barrier structures in batch, so as to reduce time for fabricating the thermoelectric material bulk and assembling the module. The thermoelectric module of the disclosure includes the diffusion barrier structure in form of single layer or multi-layer, which is capable of providing functions of cushioning stress and solving the issue of the CTE mismatch. In addition, the thermoelectric module of the disclosure is also adapted to assembling and bonding at high temperature.

Although the disclosure has been described with reference to the above embodiments, it is apparent to one of the ordinary skill in the art that modifications to the described embodiments may be made without departing from the spirit of the disclosure. Accordingly, the scope of the disclosure will be defined by the attached claims not by the above detailed descriptions.

What is claimed is:

1. A structure of a thermoelectric module, comprising:
at least one substrate;
a thermoelectric device, disposed on the at least one substrate, wherein the thermoelectric device comprises:
at least three electrode plates, having a first electrode plate and a second electrode plate disposed on the at least one substrate to serve as one terminal of the thermoelectric device;
a first type thermoelectric material, disposed on the first electrode plate, and one terminal of the first type thermoelectric material being electrically connected to the first electrode plate;
a second type thermoelectric material, disposed on the second electrode plate, and one terminal of the second type thermoelectric material being electrically connected to the second electrode plate,
wherein a third electrode plate among the at least three electrode plates is disposed on the first type thermoelectric material and the second type thermoelectric material to serve as another terminal of the thermoelectric device, and the third electrode plate is electrically connected to another terminal of the first type thermoelectric material and another terminal of the second type thermoelectric material; and
a diffusion barrier structure, disposed on the two terminals of each of the first type thermoelectric material and the second type thermoelectric material; and
an insulation protection structure, disposed surrounding the thermoelectric device.

2. The structure of the thermoelectric module of claim 1, wherein the insulation protection structure covers the thermoelectric device excluding the two terminals.

3. The structure of the thermoelectric module of claim 1, wherein the insulation protection structure substantially completely fills up a gap between the at least one substrate and the thermoelectric device.

4. The structure of the thermoelectric module of claim 1, wherein the at least one substrate comprises a first substrate and a second substrate, and the insulation protection structure comprises a barrier structure disposed between the first substrate and the second substrate and surrounding the thermoelectric device, wherein the barrier structure forms an enclosed space together with the second substrate, the first electrode plate and the second electrode plate.

5. The structure of the thermoelectric module of claim 1, further comprising at least one bonding structure, separately disposed between the at least three electrode plates and the diffusion barrier structure.

6. The structure of the thermoelectric module of claim 5, wherein the diffusion barrier structure comprises a first diffusion barrier layer and a second diffusion barrier layer, the first diffusion barrier layer is disposed between the first type thermoelectric material and the first electrode plate and disposed between the second type thermoelectric material and the second electrode plate, and the second diffusion barrier layer is disposed between the first type thermoelectric material and the third electrode plate and disposed between the second type thermoelectric material and the third electrode plate,
wherein the at least one bonding structure comprises:
a first bonding structure, disposed between the first diffusion barrier layer and the first electrode plate and disposed between the first diffusion barrier layer and the second electrode plate, and bonding the first diffusion barrier layer and the first electrode plate and bonding the first diffusion barrier layer and the second electrode plate, separately; and
a second bonding structure, disposed between the second diffusion barrier layer and the third electrode plate, and bonding the second diffusion barrier layer and the third electrode plate.

7. The structure of the thermoelectric module of claim 1, wherein the first type thermoelectric material is selected from one of a P-type thermoelectric material and an N-type thermoelectric material, the second type thermoelectric material is selected from another one of the P-type thermoelectric material and the N-type thermoelectric material, and the P-type thermoelectric material or the N-type thermoelectric material comprises Bi2Te3, GeTe, PbTe, CoSb3 or Zn4Sb3-series alloy materials.

8. The structure of the thermoelectric module of claim 1, wherein a material of the insulation protection structure is selected from glass, enamel lacquer or ceramic.

9. The structure of the thermoelectric module of claim 1, wherein the at least one substrate, the at least three electrode plates, the first type thermoelectric material and the second type thermoelectric material are bonded by a brazing method or a solid-liquid state interdiffusion bonding method or by utilizing a nano-silver material, so as to form a stack structure.
